(19) United States
(12) Patent Application Publication
(10) Pub. No.: US 2004/0022336 A1
(43) Pub. Date: Feb. 5, 2004

(54) Turbo decoder with partial interference cancellation

(76) Inventors: Xiaoyong Yu, Grayslake, IL (US); Ming Tan, Gurnee, IL (US); Mang Zhu, Vernon Hills, IL (US)

Correspondence Address: MOTOROLA, INC., 1303 EAST ALGONQUIN ROAD, IL01/3RD, SCHAUMBURG, IL, 60196

(21) Appl. No.: 10/211,848

(22) Filed: Aug. 2, 2002

(51) Int. Cl. H03D 1/04

(52) U.S. Cl. 375/346

(57) ABSTRACT

A decoder that provides partial interference cancellation in a multiple user signal includes a turbo decoder (150) that generates hard decisions of both the information and parity bits of each user signal. A multiple access interference generator (110) inputs the hard decision values along with calculated correlation coefficients between users to iteratively calculate a partial interference correction signal, which is weighted and fed back (160) to the next input of the signal before being input to the turbo decoder (150) so as to minimize the multi-user interference.

### FIELD OF THE INVENTION

This invention relates generally to communication systems, and more particularly to a decoder for use in a receiver of a turbo coded communication system.

### BACKGROUND OF THE INVENTION

Convolutional codes are often used in digital communication systems to protect transmitted information from error. Such communication systems include the Direct Sequence Code Division Multiple Access (DS-CDMA) standard IS-95, the Global System for Mobile Communications (GSM), and next generation wideband communication systems such as wideband CDMA (WCDMA). Typically in these systems, a signal is convolutionally coded into an outgoing code vector that is transmitted. At a receiver, a practical soft-output decoder, such as a Viterbi decoder as is known in the art, uses a trellis structure to perform an optimum search for the transmitted signal bits based on maximum likelihood criterion.

More recently, turbo codes have been developed that outperform conventional coding techniques. Turbo codes are generally composed of two or more convolutional codes and turbo interleavers. Turbo decoding is iterative and uses a soft output decoder to decode the individual convolutional codes. The soft outputs of one decoder feed into the next decoder or feedback to the first decoder when the decoding procedure iteratively approaches the converged final results. The soft output decoder is usually a MAP (maximum a posteriori) decoder, which requires backward and forward recursions to determine the soft output. Known MAP derivatives are also available including log-MAP, max-log-MAP, soft-output Viterbi algorithm (SOVA), and constant-log-MAP algorithms.

Turbo coding is efficiently utilized to correct errors in the case of communicating over an added white Gaussian noise (AWGN) channel. However, current and future CDMA systems allow multiple channel access by a user to speed data flow. This leads to multiple access interference (MAI), which limits the capacity of CDMA systems. Moreover, in turbo coded signals the received signal-to-noise ratio (SNR) per symbol is relatively low such that the tentative hard decisions made by the decoder may contain many errors. Consequently, estimating MAI using these erroneous hard decisions is not reliable.

One solution provides a decorrelating type of interference cancellation (IC). However, this technique is not practical for a long code system because Cholesky factorization of the correlation matrix is required, which is computationally complex and time consuming. Moreover, this approach does not address users with different transmission timing intervals (TTIs), a common case in wideband CDMA.

There is a need for a decoder that provides partial interference cancellation for a turbo coded signal, and in particular, there is a need for an improved decoder that provides partial interference cancellation without correlation matrix factorization and can be applied for users with different TTIs. It would also be of benefit to provide a decoder with a minimal increase of circuitry or computational complexity.

### BRIEF DESCRIPTION OF THE DRAWINGS

The features of the present invention, which are believed to be novel, are set forth with particularity in the appended claims. The invention, together with further objects and advantages thereof, may best be understood by reference to the following description, taken in conjunction with the accompanying drawings, in the several figures of which like reference numerals identify like elements, and in which:

FIG. 1 shows a simplified block diagram for a prior art turbo encoder;

FIG. 2 shows a simplified block diagram for a turbo encoder system for K users;

FIG. 3 shows a simplified block diagram for a prior art turbo decoder;

FIG. 4 shows a simplified block diagram of a turbo decoder with partial interference cancellation, in accordance with the present invention;

FIG. 5 shows a graph of turbo codes of differing lengths for two users;

FIG. 6 shows a graphical representation of an improvement provided by the present invention;

FIG. 7 shows a graphical representation of another improvement provided by the present invention;

FIG. 8 shows a simplified diagram for downlink interference cancellation, in accordance with the present invention; and

FIG. 9 shows a method for turbo coding with partial interference cancellation, in accordance with the present invention.

### DETAILED DESCRIPTION OF THE PREFERRED EMBODIMENT

The present invention provides a decoder that provides partial interference cancellation (PIC) for a turbo coded signal. In particular, the structure of the present invention provides partial interference cancellation without correlation matrix factorization and can be applied for users with different TTIs. Specifically, multi-stage PIC is used by introducing a weight at each interference cancellation stage to partially subtract MAI from the received signal within the turbo decoder iteration loop.

The present invention provides a new multi-stage PIC that is combined with a turbo decoder. The devices work together in a mutual support fashion, in that the PIC takes advantage of error corrected symbols fed by the turbo decoder, and the turbo decoder benefits from interference suppressed signals provided by the PIC. The present invention also provides a new structure for multi-users with different TTIs. Moreover, the present invention is applicable to multi-code interference as well as MAI. As a result, system capacity is increased and is applicable to all CDMA systems.

Typically, convolutional codes, turbo codes, and others are represented as a trellis, as is known in the art. For convenience, we will reference M states per trellis section and N trellis sections per block or frame. Maximum a posteriori type decoders (log-MAP, MAP, max-log-MAP, constant-log-MAP, etc.) utilize forward and backward generalized Viterbi recursions or soft output Viterbi algorithms (SOVA) on the trellis in order to provide soft outputs, as is known in the art. The MAP decoder minimizes the decoded bit error probability for each information bit based on all of the received signal in one encoding block or encoding frame.

Because of the Markov nature of the encoded sequence (wherein, given the current states, previous states cannot affect future states or future output branches), the a posterior bit probability can be broken into the past (beginning of trellis to the present section), the present (branch metric for the current section), and the future (end of trellis to current section). More specifically, the MAP decoder performs forward and backward recursions up to a present section wherein the past and future probabilities are used along with the present branch metric to generate an output decision. The principles of providing hard and soft output decisions on information bits are known in the art, and several variations of the described decoding methods exist. Most of the soft input-soft output (SISO) decoders considered for turbo codes are based on prior art MAP algorithms.

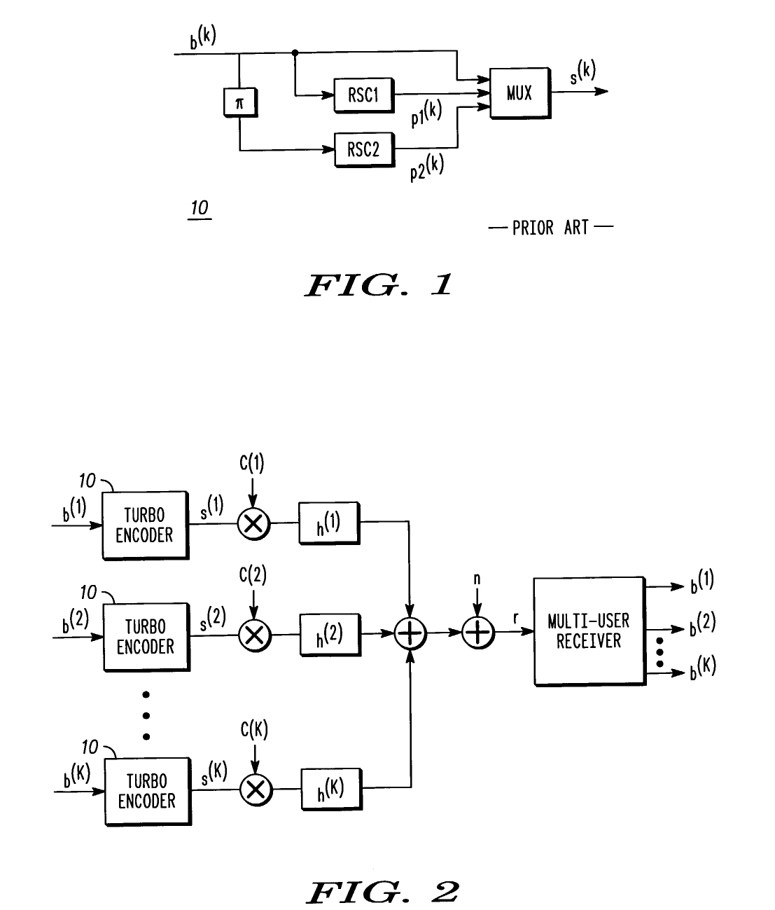

FIG. 1 shows a typical prior art turbo encoder 10 constructed in a parallel concatenation of two recursive systematic convolutional (RSC) encoders with an interleaver between them. For a user k, the output of the turbo encoder is generated by puncturing (for different coding rate) and multiplexing the information bits b^{(k)} and parity bits p₁^{(k)} and p₂^{(k)}. The output is mapped to a channel symbol sequence s^{(k)}.

In FIG. 2, a CDMA system is considered in which K users simultaneously access the same physical channel defined in frequency. For simplicity and without loss of generality, it is assumed that the channel can be characterized as additive white Gaussian noise (AWGN) and the system is synchronous. The results can be easily extended to multi-path fading channels and asynchronous systems at the price of implementation complexity increase.

In the system, each user has a binary information bit sequence b^{(k)} that is turbo encoded and mapped to channel symbol sequence s^{(k)}, which takes value either 1 or −1. The symbols are spread by spreading waveform C^{(k)} with spreading factor Q and transmitted over radio channel h^{(k)} with an additive noise factor n, representing AWGN. At the receiver end, the received signal can be expressed as

$$r = {\sum }_{k = 1}^{K} {s}^{( k )} {C}^{( k )} ⊕ {h}^{( k )} + n$$

Distortion due to interference and AWGN increases the likelihood of bit errors when a receiver attempts to decode the signal to obtain the original information bit sequence b^{(k)}. The use of turbo decoding alone in the receiver will successfully minimize bit error due to the AWGN, but something more is needed to minimize bit error due to interference.

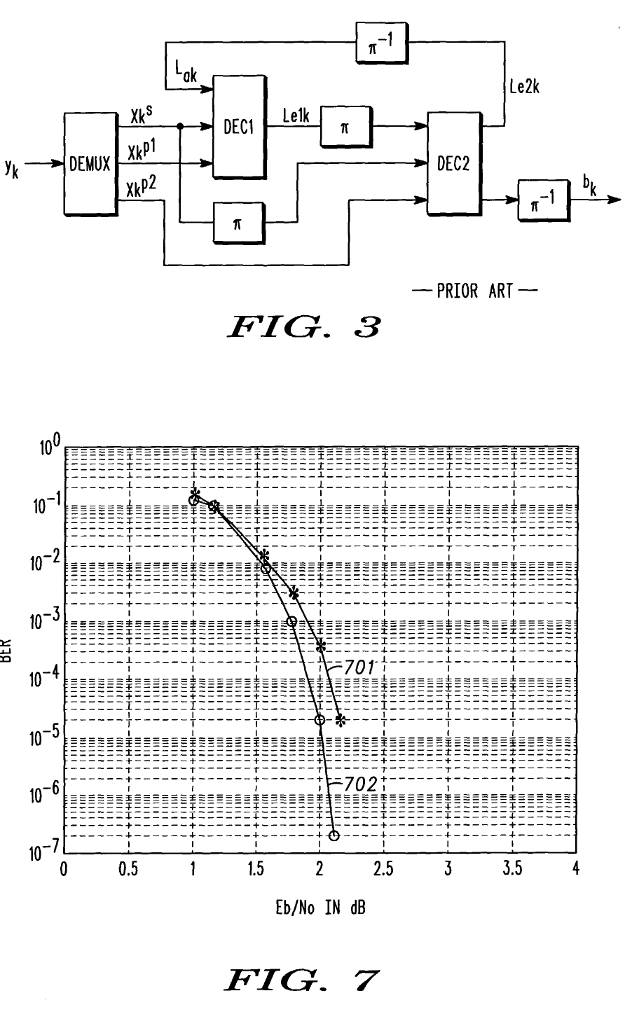

FIG. 3 shows a typical prior art turbo decoder, wherein turbo decoding is achieved in an iterative fashion, as is known in the art. The turbo decoder basically consists of two constituent decoders, denoted DEC1 and DEC2. The received signal is applied to a demultiplexer to separate the samples corresponding to information bits and coded bits xₖ^{s}, xₖ^{p1} and xₖ^{p2} representing samples for systematic bit b^{k}, and parity bits p₁ₖ and p₂ₖ, respectively. It should be noted that the k related to the turbo decoder in the following is code bit index other than user index. DEC1 and DEC2 are soft-in-soft-out (SISO) convolutional decoders corresponding to RSC1 and RSC2 in the encoder of FIG. 1. Lₑ₁ₖ and Lₑ₂ₖ denote respectively the extrinsic information generated by DEC1 and DEC2, which are passed between DEC1 and DEC2 in a “turbo” fashion.

The mechanism of the turbo decoder regarding extrinsic information Lₑ₁ₖ and Lₑ₂ₖ, interleaver π, de-interleaver π⁻¹, and the iteration process between the decoders DEC1 and DEC2 follow known algorithms. For example, the first decoder (DEC1) computes a soft output from the samples xₖ^{s}, for information bits, and xₖₚ₁, for first coded bits and the a priori information (Lₐₖ). The soft output is denoted as Lₑ₁ₖ, for extrinsic information from the first decoder. The second decoder (DEC2) is input with interleaved versions of Lₑ₁ₖ (the a priori information for DEC2), the interleaved samples xₖ^{s}, for information bits, and xₖ^{p2}, for second coded bits. The second decoder generates extrinsic information, Lₑ₂ₖ, which is deinterleaved to produce Lₐₖ, which is fed back to the first decoder. The above iteration is repeated for a predetermined number of times. Then a soft output (typically a log-likelihood ratio (LLR) of DEC2 output), which provides an estimate of the original information bits bₖ, is generated. For simplicity, a slicer can be included, as is known in the art, inside the decoders such that the decoder final output is a hard decision about bₖ, which is denoted by \hat{b}ₖ.

A novel aspect of the present invention is to modify iterative turbo decoding with multistage partial interference cancellation (PIC). That is, PIC is adapted to the turbo decoding iteration loop. To achieve PIC within turbo decoding iterations, a traditional turbo decoder can be modified. A conventional turbo decoder only calculates the log-likelihood ratio (LLR) or soft decision of information bits bₖ. The present invention generates soft decisions for all channel symbols, including the calculation of soft decisions associated with parity bits, resulting in a negligible increase in complexity. The LLR of parity bit pₖ is defined as

$$L ( {p}_{k} ) = ln \frac{p ( {p}_{k} = 1 \vert u )}{p ( {p}_{k} = 0 \vert u )} = ln \frac{p ( {p}_{k} = 1 , u )}{p ( {p}_{k} = 0 , u )}$$

where u denotes input signal for one turbo code frame and p(.) represents a probability density function. We note that for i=0,1,

$$p ( {p}_{k} = i , u ) = {\sum }_{{( n , m )}_{{p}_{k} = i}} p ( n , m , u )$$

The summation is over all the transitions, from state n to state m at time k, of the encoder trellis with the coded bit output pₖ=i. It can be shown that

p(n, m, u)=αₖ₋₁(n)γₖ(n, m)βₖ(m)

where the α, γ and β parameters are calculated for the information bits in a regular turbo decoder. For simplicity, the notation u has been dropped in all these parameters.

The LLR for each parity bit is

$$L ( {p}_{k} ) = ln \frac{{\sum }_{( m , n ) ∈ {P}^{1}} {α}_{k - 1} ( n ) {γ}_{k} ( n , m ) {β}_{k} ( m )}{{\sum }_{( m , n ) ∈ {P}^{0}} {α}_{k - 1} ( n ) {γ}_{k} ( n , m ) {β}_{k} ( m )} .$$

The probability that a decoded bit is equal to 1 (or 0), given the received sequence, is composed of a product of terms due to the Markov property of the code. The Markov property states that the past and the future are independent given the present. The present, γₖ(n,m), called the branch metric represents the transition probability from state n at time k−1 to state m at time k, given the current received samples uₖ, here uₖ denotes a pair of (xₖ^{s}, xₖ^{p}). The past, αₖ₋₁(m), is the probability of being in state m at time k−1 with the received sequence {u₁, . . . , uₖ₋₁}, and the future, βₖ(M), is probability of generating the received sequence {uₖ₊₁, . . . , u_{N}} from state m at time k. P¹ and P⁰ denote those state transitions that correspond to pₖ=1 and pₖ=0, respectively.

The probability αₖ(M) can be expressed as function of αₖ₋₁(m) and γₖ(n,m) in the forward recursion

$${α}_{k} ( m ) = {\sum }_{m = 0}^{M - 1} {α}_{k - 1} ( n ) {γ}_{k} ( n , m ) m = 0 , … , M - 1$$

with M being the number of states of the encoder, and βₖ(n) can be calculated using the backward recursion from βₖ₊₁(n) and γₖ(n,m) as

$${β}_{k} ( n ) = {\sum }_{m = 0}^{M - 1} {β}_{k + 1} ( m ) {γ}_{k} ( n , m ) n = 0 , … , M - 1$$

where γₖ(n,m) is the branch metric.

It is noted that all these recursions are performed during the normal turbo decoding process for the information bits. The LLR values for the coded bits, L(pₖ), are obtained in the same way as the LLR values for the information bits, L(bₖ), except the summation is calculated over a different group of transitions. These LLR values are then used for partial interference calculation using a modified turbo decoder, in accordance with the present invention.

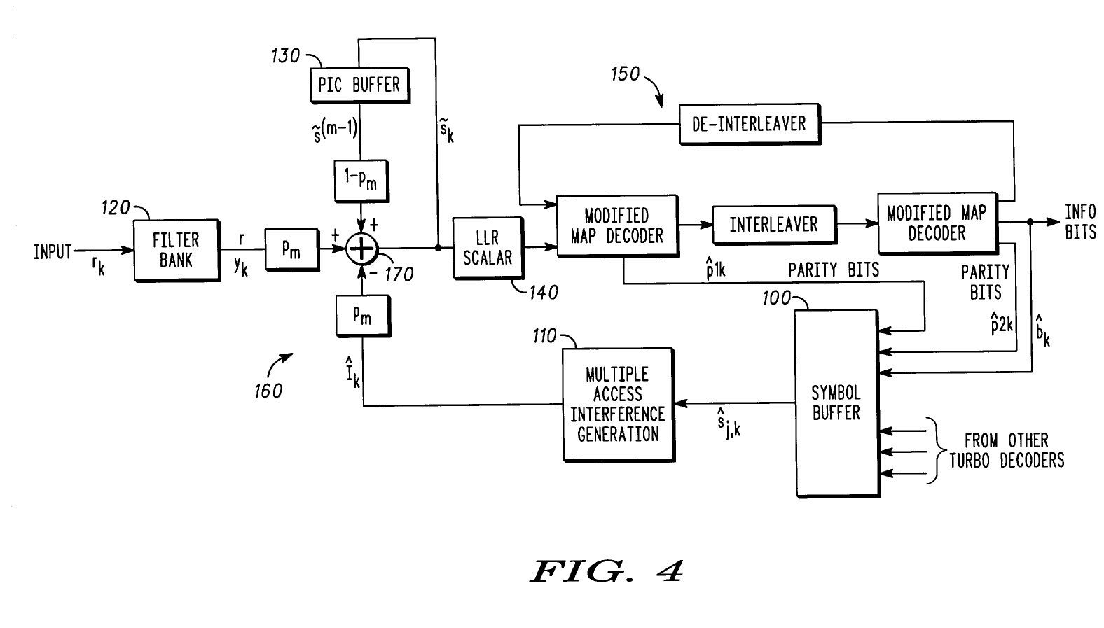

Up to this point, the only additional computation to generate soft decisions for parity bits has been to perform summation (max* operation in practice) over different state transition pairs. Once the log-likelihood ratios of parity bits are calculated, the hard decisions of the information bits and parity bits as \hat{b}ₖ, \hat{p}₁ₖ and \hat{p}₂ₖ, respectively, are determined by the following equation.

$${\hat{c}}_{k} = \{ \begin{matrix}1 & if L ( {c}_{k} ) \geq 0 \\ 0 & if L ( {c}_{k} ) < 0\end{matrix}$$

where ĉₖ represents either \hat{b}ₖ, \hat{p}₁ₖ or \hat{p}₂ₖ. It should be pointed out that the output of a regular turbo decoder is usually LLR and one needs an additional slicer to perform the hard decision above. However, for simplicity, such a slicer is included inside the turbo decoder depicted in FIG. 4, so that the hard decisions are directly sent out from the corresponding constituent decoder.

The hard decisions, \hat{b}ₖ, \hat{p}₁ₖ and \hat{p}₂ₖ, are then multiplexed and mapped to the corresponding channel symbols as

$${\hat{s}}_{j} = \{ \begin{matrix}1 & if & {\hat{c}}_{k} = 0 \\ - 1 & if & {\hat{c}}_{k} = 1\end{matrix}$$

Finally, MAI at the m^{th} stage is calculated as

$${\hat{I}}_{k}^{( m )} = {\sum }_{j = 1 , j \neq k}^{K} {ρ}_{jk} {\hat{s}}_{j}^{( m - 1 )}$$

where ŝⱼ^{(m-1)} is estimated channel symbol before the m^{th} interference cancellation stage. For user k (using k to denotes user in the following), the input to turbo decoder \tilde{s}ₖ^{(m)} for the next iteration is updated at m^{th} PIC stage:

$${\tilde{s}}_{k}^{( m )} = {p}_{m} ( {y}_{k} - {\hat{I}}_{k}^{( m )} ) + ( 1 - {p}_{m} ) {\tilde{s}}_{k}^{( m - 1 )}$$

where rₖ denotes output of maximum ratio combining (MRC) for interested user k.

In practice, the estimated symbols cannot be all correct, but due to the very large turbo coding gain and the fact that the PIC is implemented in the feedback loop, the symbol error probability becomes smaller and smaller as the iteration going on. In this technique, the interference canceller benefits from more reliable hard decisions generated by the turbo decoder and the turbo decoder takes advantage of interference suppressed input signal provided by the interference canceller. Therefore, the MAI can be significantly suppressed in an iterative fashion, which is in accordance with turbo decoding procedure and consequently improve receiver performance.

FIG. 4 shows a turbo decoder with partial interference cancellation (PIC), in decoding a received turbo coded input signal, in accordance with the present invention. The decoder includes a turbo decoder 150 and an PIC feedback loop 160. The turbo decoder includes two constituent decoders connected in a typical iterative loop configuration. The turbo decoder decodes the information bits and coded bits of the input signal and calculates hard decisions based on soft decisions for the information bits and coded bits of the input signal. Typically, the coded bits are parity bits that are punctured, and the soft decision values are LLR values. The recursion updates and soft outputs are calculated using a MAP algorithm or one of the MAP derivatives (i.e., log-MAP, max-log-MAP, constant-log-MAP, etc.), or a SOVA or Generalized Viterbi algorithm. Preferably, the constituent decoders are modified, such as with slicers for example, to provide hard decision values for the information bits and coded bits.

The PIC feedback loop 160 is coupled to the turbo decoder and is adapted to receive hard decision values for the coded and information bits from the turbo decoder as shown. The feedback loop includes an symbol buffer 100 that inputs the hard decision on each bit provided by the decoder to calculate PIC. An MAI generator 110 applies a correction to the next input of the signal before being input to the turbo decoder 150 so as to minimize the interference.

One novel aspect of the present invention is having the symbol buffer 100 and MAI generator 110 implemented in an iterative loop 160 of the turbo decoder 150. Values applied to the generator are calculated in each turbo decoding iteration. The MAI generator can be operated either in a synchronous fashion with turbo decoding iteration (the number of IC stages is equal to the number of turbo decoding iterations) or in an asynchronous fashion (the numbers are different).

In operation, an input signal, rₖ, is passed through a matched filter bank 120 (or maximum ratio combiner (MRC) in the case of multipath channel), and sampled at symbol rate. In an AWGN example, as represented here, the matched filtering is equivalent to de-spreading the received signal by pseudorandom number (PN) code c^{(k)} and summing takes place over one symbol interval. The output of the matched filter bank is a set of minimum sufficient statistics for transmitted symbols and may be expressed

$$y = {( {y}_{1}^{( 1 )} , {y}_{1}^{( 2 )} , ⋯ , {y}_{1}^{( K )} , {y}_{2}^{( 1 )} , {y}_{2}^{( 2 )} , ⋯ , {y}_{2}^{( K )} , {y}_{3}^{( 1 )} , ⋯ , {y}_{N}^{( 1 )} , ⋯ , {y}_{N}^{( K )} )}^{T}$$

Here it is assumed that the length of symbol sequence for each user is N for simplicity. The first element in y can be derived as

$$\begin{matrix}{y}_{l}^{( 1 )} = \frac{1}{Q} {\sum }_{j = 1}^{Q} {c}_{j}^{( 1 )} ( {c}_{j}^{( 1 )} {s}_{1}^{( 1 )} {h}^{( 1 )} + {c}_{j}^{( 2 )} {s}_{1}^{( 2 )} {h}^{( 2 )} + ⋯ + {c}_{j}^{( K )} {s}_{1}^{( K )} {h}^{( K )} + {n}_{1} ) \\ = {s}_{1}^{( 1 )} {h}^{( 1 )} + {ρ}_{12} ( 1 ) {s}_{1}^{( 2 )} {h}^{( 2 )} + {ρ}_{13} ( 1 ) {s}_{1}^{( 3 )} {h}^{( 3 )} + ⋯ + {ρ}_{1 K} ( 1 ) {s}_{2}^{( K )} {h}^{( K )} + {z}_{1}\end{matrix}$$

where correlation coefficients are defined as

$${ρ}_{1 k} ( 1 ) = \frac{1}{Q} {\sum }_{j = 1}^{Q} {c}_{j}^{( 1 )} {c}_{j}^{( k )} \qquad for k = 2 , 3 , … , K$$

The (K+1)^{th} element of y is

$$\begin{matrix}{y}_{2}^{( 1 )} = \frac{1}{Q} {\sum }_{j = 1}^{Q} {c}_{j + Q}^{( 1 )} ( {c}_{j + Q}^{( 1 )} {s}_{2}^{( 1 )} {h}^{( 1 )} + {c}_{j + Q}^{( 2 )} {s}_{2}^{( 2 )} {h}^{( 2 )} + ⋯ + {c}_{j + Q}^{( K )} {s}_{2}^{( K )} {h}^{( K )} + {n}_{K + 1} ) \\ = {s}_{2}^{( 1 )} {h}^{( 1 )} + {ρ}_{12} ( 2 ) {s}_{2}^{( 2 )} {h}^{( 2 )} + {ρ}_{13} ( 2 ) {s}_{2}^{( 3 )} {h}^{( 3 )} + ⋯ + {ρ}_{1 K} ( 2 ) {s}_{2}^{( K )} {h}^{( K )} + {z}_{K + 1}\end{matrix}$$

where the correlation coefficients are

$${ρ}_{1 k} ( 2 ) = \frac{1}{Q} {\sum }_{j = 1}^{Q} {c}_{j + Q}^{( 1 )} {c}_{j + Q}^{( k )} for k = 2 , 3 , … , K$$

In general,

$$\begin{matrix}{y}_{n}^{( k )} = \frac{1}{Q} {\sum }_{j = 1}^{Q} {c}_{j + ( n - 1 ) Q}^{( k )} ( {c}_{j + ( n - 1 ) Q}^{( 1 )} {s}_{n}^{( 1 )} {h}^{( 1 )} + {c}_{j + ( n - 1 ) Q}^{( 2 )} {s}_{n}^{( 2 )} {h}^{( 2 )} + ⋯ + {c}_{j + ( n - 1 ) Q}^{( K )} {s}_{n}^{( K )} {h}^{( K )} + {n}_{( n - 1 ) K + k} ) \\ = {ρ}_{k1} ( n ) {s}_{n}^{( 1 )} {h}^{( 1 )} + ⋯ + {ρ}_{k ( k - 1 )} ( n ) {s}_{n}^{( k - 1 )} {h}^{( k - 1 )} + {s}_{n}^{( k )} {h}^{( k )} + {ρ}_{k ( k + 1 )} ( n ) {s}_{n}^{( k + 1 )} {h}^{( k + 1 )} + ⋯ + \\ {ρ}_{kK} ( n ) {s}_{n}^{( K )} {h}^{( K )} + {z}_{( n - 1 ) K + k}\end{matrix}$$

where

$${ρ}_{mk} ( n ) = \frac{1}{Q} {\sum }_{j = 1}^{Q} {c}_{j + ( n - 1 ) Q}^{( m )} {c}_{j + ( n - 1 ) Q}^{( k )} for m \neq k and n = 1 , 2 , … , N$$

In matrix form, we have

y=Rs+z

where z is additive noise, s is a vector of transmitted symbols arranged in a special order, i.e.,

$$s = {( {s}_{1}^{( 1 )} , {s}_{1}^{( 2 )} , ⋯ , {s}_{1}^{( K )} , {s}_{2}^{( 1 )} , {s}_{2}^{( 2 )} , ⋯ , {s}_{2}^{( K )} , {s}_{3}^{( 1 )} , ⋯ , {s}_{N}^{( 1 )} , ⋯ , {s}_{N}^{( K )} )}^{T}$$

and R is an NK by NK correlation matrix, which absorbs channel gains and is normalized such that its diagonal elements are all ones. In our case here, R is block diagonal matrix where each block is K by K matrix determined by corresponding correlation coefficients and channel gains, for example,

$$\begin{matrix}\begin{matrix}\begin{matrix}\begin{matrix}R = diag ( R ( 1 ) , R ( 2 ) , ⋯ , R ( N ) ) \\ where\end{matrix} \\ R ( n ) = [ \begin{matrix}1 & {ρ}_{12}^{′} ( n ) & ⋯ & {ρ}_{1 K}^{′} ( n ) \\ {ρ}_{21}^{′} ( n ) & 1 & ⋯ & {ρ}_{2 K}^{′} ( n ) \\ ⋯ & ⋯ & ⋯ & ⋯ \\ {ρ}_{K1}^{′} ( n ) & {ρ}_{K2}^{′} ( n ) & ⋯ & 1\end{matrix} ]\end{matrix} \\ and\end{matrix} \\ {ρ}_{ij}^{′} ( n ) = {h}^{( j )} {ρ}_{ij} ( n ) / {h}^{( i )}\end{matrix}$$

with the values of pᵢⱼ being correlation coefficients between user j and k to be used in partial interference calculations as will be described below.

The basic idea of interference cancellation (IC) is to generate an interference signal based on recovered channel symbols and subtract it from received signal. In the art, the IC algorithms can be classified as parallel and successive ones and usually implemented in multistage structure. Multistage parallel IC has received considerable attention due to its simple structure and less decision delay. However, the conventional multistage parallel IC (total IC) does not produce satisfactory performance due to improper interference estimates (resulting from poor channel and unreliable channel symbol estimates). A prior art partial IC (PIC) technique has also been introduced, which alleviates the problems by introducing a weight at each stage to mitigate the effect of improperly estimated channel and unreliable channel symbols. However, in the case of a turbo encoded signal, more performance gain can be obtained by using present invention.

Multistage PIC can be summarized in the following operations for k^{th} user's bit (equivalent to channel symbol for BPSK modulation) at m^{th} stage:

$$\begin{matrix}\begin{matrix}\begin{matrix}{\tilde{s}}_{k}^{( m )} = {p}_{m} ( {y}_{k} - {\hat{I}}_{k}^{( m )} ) + ( 1 - {p}_{m} ) {\tilde{s}}_{k}^{( m - 1 )} \\ {\tilde{s}}_{k}^{( m )} = sgn ( {\tilde{s}}_{k}^{( m )} )\end{matrix} \\ where\end{matrix} \\ {\hat{I}}_{k}^{( m )} = {\sum }_{j = 1 , j \neq k}^{K} {ρ}_{jk} {\hat{s}}_{j}^{( m - 1 )}\end{matrix} \qquad ( 1 )$$

represents the estimated multiple access interference (MAI) calculated from other users' tentative hard decisions at stage m−1, pₘ denotes the partial cancellation weight at stage m (conventional total-IC corresponding to pₘ=1), yₖ and \tilde{s}ₖ^{(m)} are respectively the received signal after the matched filter and the “soft” decision at stage m for user k, pⱼₖ is the correlation coefficients between user j and k, which absorbs channel and all other gain scalars. The weighting pₘ is determined empirically to provide the best interference cancellation.

Referring back to FIG. 4 and Equation 1 above, during iterations of the decoder 150 (and any other decoder sharing the physical channel), hard decisions of the information and parity bits are sent to the symbol buffer 100, which generates channel symbols ŝₖ^{(m)} that are multiplied and summed with the correlation coefficients pⱼₖ to determine the multiple access interference (MAI), Îₖ^{(m)}. A weighting factor, pₘ, is applied to the MAI, which is subsequently subtracted from the input signal yₖ (=Rs+z), also weighted with pₘ at a summing block 170. Simultaneously, a previous version of the input channel symbol, \tilde{s}ₖ^{(m-1)}, stored in a PIC buffer 130 is also weighted with 1-pₘ and applied to the summing block 170. This results in Equation 1. The resultant partially interference cancelled signal can then applied to an LLR scalar 140 (for a Log-MAP turbo decoder) to scale the input signal l/var(n) (where var(n) is noise variance) for reapplication to the next iteration of the decoder 150. However, a scalar is not necessary for all turbo decoders, such as a Max-log-MAP turbo decoder, for example.

Traditional IC works well for uncoded signals where received signal SNR is relatively high, such that the decisions on s have a few errors and are relatively reliable. However, for coded signals, especially for turbo encoded signals where, due to the expected huge coding gain, the raw SNR of received signal is very low such that conventional IC does not work any more. The present invention alleviates this problem by providing partial IC within turbo decoding.

The present invention also addresses the practical issues where the system users may have different transmission timing intervals (TTIs) and access the same physical channel asynchronously. This occurs in real CDMA systems such as Universal Mobile Telecommunications System (UMTS) WCDMA Frequency Division Duplex (FDD) mode. In this case, received turbo code frames are not aligned and have different length. One solution to the problem is to use a symbol buffer 100, which should be able to hold largest possible code frame (5114×3+12 bits for UMTS WCDMA) for all users, as shown in FIG. 4. This buffer stores the most reliable bits from all the turbo-coded users. The most reliable bits usually correspond to most recent turbo decoding iterations for different users. One purpose of the symbol buffer is to de-couple the decoding iterations for all users while conduct MAI estimation and subtraction such that each turbo decoder works asynchronously at its own pace. For instance, at one time when MAI is calculated, the buffer may store bits corresponding to the 5^{th} iteration of user 1 and the 2^{nd} iteration of user 2 and the final iteration of user 3 and so on, but they are all the most reliable ones that can be obtained at that moment. The estimated MAI is then subtracted from all turbo decoder inputs as need. Obviously, this estimated MAI is the “best” one that can be had at that stage.

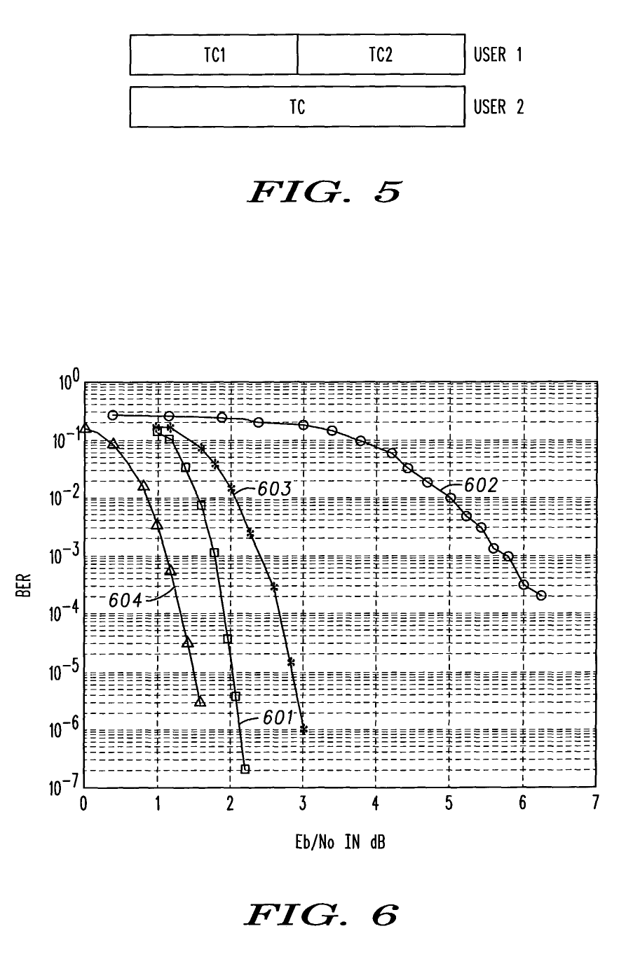

As an example, consider two users with different turbo code length. User 1 has turbo code length which is half that of user 2, as shown in FIG. 5. Without loss of generality and for simplicity, we assume the throughputs of the turbo decoder for user 1 and the turbo decoder for user 2 are the same. In other words, when user 2 decodes one turbo code, user 1 will decode 2 turbo codes. Assume both turbo decoders use ten iterations to decode one turbo code and PIC is performed at turbo iterations 4, 6 and 8 (3-stage PIC). Before user 1 starts iteration 5 for the first turbo code (TC1), the MAI is calculated and subtracted by using symbols of user 2 recovered at 2nd iteration for its turbo code (TC); at the beginning of iteration 7 for TCI, the MAI is computed based on symbols of user 2 recovered at 3rd iteration of TC; and the MAI for the last PIC stage is determined by using the symbols of user 2 recovered at the 4th iteration of TC. Similarly, the MAI for user 1 corresponding to the second turbo code (TC2) is computed by using the symbols of user 2 at iterations 7, 8 and 9. On the other hand, before user 2 starts iteration 5 for TC, MAI is calculated by using the symbols of user 1 corresponding to the 8th iteration of TC1 and simply sliced symbols for TC2 (iteration 0). At the beginning of iteration 7 for TC, MAI is based on the final decisions of TC1 and the 2nd iteration of TC2. The last PIC stage of user 2 is based on the final decision of TC1 and the 6th iteration for TC2 of user 1.

Obviously, the performance of the present invention for users with different TTIs may degrade slightly. Simulation result confirms that this performance degradation is about 0.25 dB. However, the performance is observably better than that of conventional multistage PIC where only simply sliced symbols are used to determine MAI.

FIG. 6 shows simulation results using the turbo decoding with partial interference cancellation, in accordance with the present invention, compared with other techniques. The simulation assumed four users with SF=4 and V=3 km. In particular, the bit error rate (BER) for each of the interference cancellation technologies is shown versus energy per bit over noise density. The weighting in this simulation was selected as {0, 0, 0, 0.3, 0.4, 0.55, 0.7, 0.75, 0.8, 0.85, 0.9, 1} for iterations 1 to 12.

As can be seen, the partial interference cancellation technique of the present invention, shown as curve 601, outperforms conventional MRC, shown as curve 602, by more than 4 dB and outperforms conventional PIC, shown as curve 603, by about 0.9 dB (approximately 27% capacity increase). Also, the performance of the present invention is only about 0.5 dB away from a single user system, shown as curve 604, at a BER of 10⁻⁶. Performance degradation of the present invention for four users with different TTIs (i.e. different code lengths), is shown as curve 701 in FIG. 7. As can be seen, the degradation is only about 0.25 dB compared to the performance with the same TTIs, shown as curve 702.

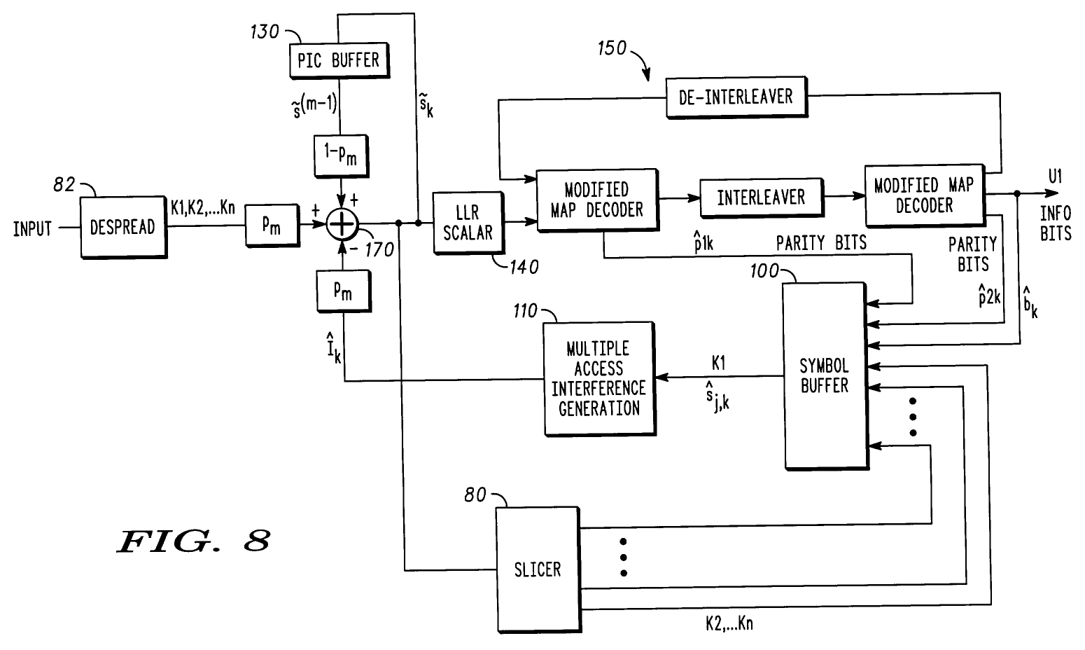

Advantageously, the present invention can also be applied to the downlink interference cancellation, as shown in FIG. 8. In a Third Generation Partnership Project (3GPP) cellular system, the user equipment can be receiving high-speed data that requires more than one code channel. Examples are the Time Division Duplex (TDD) mode of 3GPP system, High Speed Downlink Packet Data (HSDPA) in 3GPP and 1xEV-DV in 3GPP2, where multi-codes are assigned for both uplink and downlink multi-user channels. The orthogonality among these code channels will no longer be maintained due to the delay spread. Moreover, variable spreading factors for each user can be used in the system. All the spreading factors being used, would not be known to any particular user.

In the downlink, the interference can be divided into two parts. The first part is from the multiple code channels assigned to the desired user, and the second part is from all the other code channels assigned to the other users. The present invention treats the first part of interference the same way as described above, that is, the turbo decoded bits belonging to the user of interest are fed back to reproduce the interference, which is then to be subtracted from the received signal in the next iteration. Thus, the PIC loop and the turbo decoder loop are combined in a single iteration loop. The second part of interference is treated the same as the conventional PIC method previously described, with the addition of a slicer 80 coupled between the input signal and the symbol buffer, the slicer is simply used to make hard decisions for the code channels of interfering users in order to reproduce the interference. The symbol buffer stores the turbo decoder's hard decision along with the hard decisions based on the other users' soft output from a conventional PIC algorithm.

It is assumed that there are total of K downlink code channels assigned to n users, with K1, K2, . . . , Kn codes assigned to user U1, U2, . . . , Un, respectively, where K1+K2+. . . +Kn=K. Without loss of generality, Ut is assumed to be the desired user. The present invention puts the turbo decoder of the K1 codes of user U1 in the PIC loop, and process all other K2+K3+. . . +Kn codes using the conventional PIC algorithm.

In the downlink model of the interference cancellation, the variable spreading waveforms (C(k) in FIG. 2) associated with other users may not be known to the desired user. An effective spreading code and effective data symbol can be used to deal with this problem. For example, if the desired user Ut uses the spreading factor of 16, a despreader 82 can be used to despread the received signal with all sixteen Walsh codes of order 16, and use the resulting symbols with enough energy to reproduce the effective multi-user interference to Ut. This is done in conjunction with the iterative partial interference cancellation as described above. Alternatively, the system may indicate the spreading code being used so that a despread search in not needed.

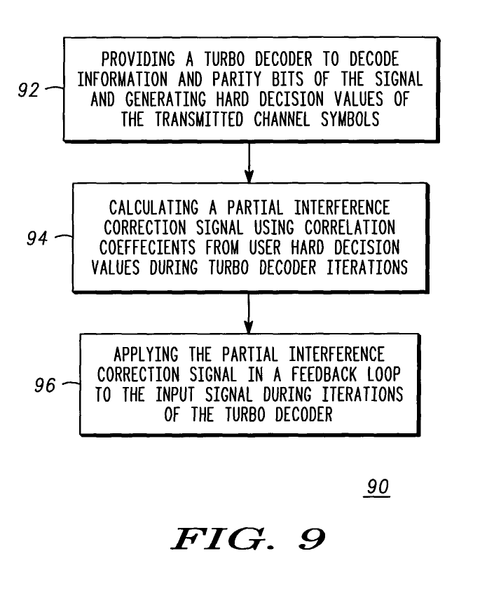

FIG. 9 shows a flow chart representing a method 90 of partial interference cancellation in a received turbo coded signal having multiple users in accordance with the present invention. A first step 92 of the method is providing a turbo decoder (as shown in FIG. 4) having two recursion processors connected in an iterative loop. The turbo decoder decodes the information bits and the coded bits of the input signal and calculates soft decision values for the information bits and coded bits of the input signal. Typically, the coded bits are parity bits that may or may not be punctured, and the soft decision values are LLR values. Hard decision values of the transmitted channel symbols based on the soft decision values from the turbo decoder are also generated. Preferably, the recursion processors of the turbo decoder are modified to provide hard decision values of the coded bits and information bits. Hard decisions can be provided from other turbo decoders for other users also, or can be provided by a slicer that provides hard decisions for the coded signals of interfering users.

A next step 94, includes calculating a partial interference correction signal using correlation coefficients determined between users and the hard decision values during decoding iterations of the at least one turbo decoder. Specifically, the interference signal is

$${\hat{I}}_{k}^{( m )} = {\sum }_{j = 1 , j \neq k}^{K} {ρ}_{jk} {\hat{s}}_{j}^{( m - 1 )}$$

where k is the user, m is the stage of PIC, ŝⱼ^{m-1)} is the hard decisions from other users at stage m−1, and pⱼₖ is the correlation coefficients between user j and k, summed over all users K.

In a preferred embodiment, and additional step is included for weighting the partial interference cancellation signal using

$$\begin{matrix}{\tilde{s}}_{k}^{( m )} = {p}_{m} ( {y}_{k} - {\hat{I}}_{k}^{( m )} ) + ( 1 - {p}_{m} ) {\tilde{s}}_{k}^{( m - 1 )} \\ {\hat{s}}_{k}^{( m )} = sgn ( {\tilde{s}}_{k}^{( m )} )\end{matrix}$$

where pₘ denotes the partial cancellation weight at stage m, and yₖ and \tilde{s}ₖ^{(m)} are respectively the received signal and the soft decision at stage m for user k. As can be seen weighting can also be applied to the received signal and the soft decision at stage m for user k. Optionally, this step 94 can include despreading a received downlink signal of multiple users with all the Walsh codes of the same order as the signal of the user of interest, and using only the resulting symbols with enough energy to reproduce the effective multi-user interference.

A next step 96 is applying the partial interference correction signal in a feedback loop to the input signal during iterations of the at least one turbo decoder to minimize interference.

In a preferred embodiment, the providing step 92 occurs asynchronously with the calculating step 94 for each user, to accommodate differing transmit timing intervals.

While specific components and functions of the turbo decoder with partial interference cancellation are described above, fewer or additional functions could be employed by one skilled in the art within the broad scope of the present invention. The invention should be limited only by the appended claims.

What is claimed is:

1. A decoder that provides partial interference cancellation in decoding a received turbo coded signal having multiple users, the decoder comprising:
at least one turbo decoder with two recursion processors connected in an iterative loop, the at least one turbo decoder for decoding information and parity bits of each user signal and generating the transmitted channel symbols;
a symbol buffer coupled to the at least one turbo decoder, the symbol buffer adapted to receive the hard decision values for the coded and information bits from the at least one turbo decoder; and
a multiple access interference generator coupled to the symbol buffer and connected in an iterative feedback loop with the turbo decoder, the generator inputs the hard decision values along with calculated correlation coefficients between users derived and updated from a previous signal frame to calculate a partial interference correction signal, which is applied the next input of the signal before being input to the turbo decoder so as to minimize the multi-user interference.

2. The decoder of claim 1, wherein the symbol buffer inputs decisions from various users asynchronously.

3. The decoder of claim 1, wherein the recursion processors use a LLR value calculated for the information and parity bits to derive a hard decision value of the transmitted channel symbols that is coupled to the multiple access interference generator.

4. The decoder of claim 1, wherein the partial interference cancellation signal is
$${\hat{I}}_{k}^{( m )} = {\sum }_{j = 1 , j \neq k}^{K} {ρ}_{jk} {\hat{s}}_{j}^{( m - 1 )}$$
where k is the user, m is the stage of the input signal, ŝⱼ^{m-1)} is the hard decisions from other users at stage m−1, and pⱼₖ is the correlation coefficients between user j and k, summed over all users K.

5. The decoder of claim 1, wherein partial interference correction signal is weighted before being applied to the input signal.

6. The decoder of claim 5, wherein the weighting is applied as
$$\begin{matrix}{\tilde{s}}_{k}^{( m )} = {p}_{m} ( {y}_{k} - {\hat{I}}_{k}^{( m )} ) + ( 1 - {p}_{m} ) {\tilde{s}}_{k}^{( m - 1 )} \\ {\hat{s}}_{k}^{( m )} = sgn ( {\tilde{s}}_{k}^{( m )} )\end{matrix}$$
$$where$$
$${\hat{I}}_{k}^{( m )} = {\sum }_{j = 1 , j \neq k}^{K} {ρ}_{jk} {\hat{s}}_{j}^{( m - 1 )}$$
represents the estimated multiple access interference (MAI) calculated from ŝⱼ^{m-1)}, the other users' tentative hard decisions at stage m−1, pₘ denotes the partial cancellation weight at stage m, yₖ and \tilde{s}ₖ^{(m)} are respectively the received signal and the soft decision at stage m for user k, and pⱼₖ is the correlation coefficients between user j and k.

7. The decoder of claim 1, further comprising an input buffer for the turbo decoder, wherein the input buffer despreads a received downlink signal of multiple users with all the Walsh codes of the same order as the signal of the user of interest, and the decoder uses only the resulting symbols with enough energy to reproduce the effective multi-user interference to the user of interest.

8. The decoder of claim 1, further comprising a slicer coupled between the input signal and the symbol buffer, the symbol buffer stores the hard decisions from the turbo decoder along with the hard decisions generated by the slicer from soft outputs of interfering users.

9. A decoder that provides partial interference cancellation in decoding a received turbo coded signal having multiple users, the decoder comprising:
at least one turbo decoder with two recursion processors connected in an iterative loop, the at least one turbo decoder for decoding information and parity bits of each user signal and generating hard decisions of the transmitted channel symbols;
a symbol buffer coupled to the at least one turbo decoder, the symbol buffer adapted to receive the hard decision values for the coded and information bits from the at least one turbo decoder; and
a multiple access interference generator coupled to the symbol buffer and connected in an iterative feedback loop with the turbo decoder, the generator inputs the hard decision values along with calculated correlation coefficients between users derived and updated from a previous signal frame to calculate a partial interference correction signal, which is weighted and applied the next input of the signal before being input to the turbo decoder so as to minimize the multi-user interference.

10. The decoder of claim 9, wherein the symbol buffer inputs decisions from various users asynchronously.

11. The decoder of claim 9, wherein the partial interference cancellation signal is
$${\hat{I}}_{k}^{( m )} = {\sum }_{j = 1 , j \neq k}^{K} {ρ}_{jk} {\hat{s}}_{j}^{( m - 1 )}$$
where k is the user, m is the stage of the input signal, ŝⱼ^{(m-1)} is the hard decisions from other users at stage m−1, and pⱼₖ is the correlation coefficients between user j and k, summed over all users K.

12. The decoder of claim 11, wherein the weighting is applied as
$$\begin{matrix}{\tilde{s}}_{k}^{( m )} = {p}_{m} ( {y}_{k} - {\hat{I}}_{k}^{( m )} ) + ( 1 - {p}_{m} ) {\tilde{s}}_{k}^{( m - 1 )} \\ {\hat{s}}_{k}^{( m )} = sgn ( {\tilde{s}}_{k}^{( m )} )\end{matrix}$$
where, pₘ denotes the partial cancellation weight at stage m, and yₖ and \tilde{s}ₖ^{(m)} are respectively the received signal and the soft decision at stage m for user k.

13. The decoder of claim 9, further comprising an input buffer for the turbo decoder, wherein the input buffer despreads a received downlink signal of multiple users with all the Walsh codes of the same order as the signal of the user of interest, and the decoder uses only the resulting symbols with enough energy to reproduce the effective multi-user interference.

14. The decoder of claim 9, further comprising a slicer coupled between the input signal and the symbol buffer, the symbol buffer stores the hard decisions from the turbo decoder along with the hard decisions generated by the slicer from soft outputs of interfering users.

15. A method of partial interference cancellation in a received turbo coded signal having multiple users, the method comprising the steps of:
providing at least one turbo decoder with two recursion processors connected in an iterative loop, and the at least one turbo decoder decoding the information and parity bits of the signal and generating hard decision values of the transmitted channel symbols;
calculating a partial interference correction signal using correlation coefficients determined between users from the hard decision values during iterations of the at least one turbo decoder; and
applying the partial interference correction signal in a feedback loop to the input signal during iterations of the at least one turbo decoder.

16. The method of claim 15, wherein the providing step occurs asynchronously with the calculating step for each user.

17. The method of claim 15, wherein the calculating step includes calculating the partial interference cancellation signal as
$${\hat{I}}_{k}^{( m )} = {\sum }_{j = 1 , j \neq k}^{K} {ρ}_{jk} {\hat{s}}_{j}^{( m - 1 )}$$
where k is the user, m is the stage of the input signal, ŝⱼ^{(m-1)} is the hard decisions from other users at stage m−1, and pⱼₖ is the correlation coefficients between user j and k, summed over all users K.

18. The method of claim 15, further comprising the step of weighting the partial interference cancellation signal using
$$\begin{matrix}{\tilde{s}}_{k}^{( m )} = {p}_{m} ( {y}_{k} - {\hat{I}}_{k}^{( m )} ) + ( 1 - {p}_{m} ) {\tilde{s}}_{k}^{( m - 1 )} \\ {\hat{s}}_{k}^{( m )} = sgn ( {\tilde{s}}_{k}^{( m )} )\end{matrix}$$
and wherein the calculating step includes calculating the partial interference cancellation signal as
$${\hat{I}}_{k}^{( m )} = {\sum }_{j = 1 , j \neq k}^{K} {ρ}_{jk} {\hat{s}}_{j}^{( m - 1 )}$$
calculated from ŝⱼ^{(m-1)}, the other users' tentative hard decisions at stage m−1, pₘ denoting the partial cancellation weight at stage m, yₖ and \tilde{s}ₖ^{(m)} are respectively the received signal and the soft decision at stage m for user k, and pⱼₖ is the correlation coefficients between user j and k.

19. The method of claim 15, wherein the calculating step includes despreading a received downlink signal of multiple users with all the Walsh codes of the same order as the signal of the user of interest, and using only the resulting symbols with enough energy to reproduce the effective multi-user interference.

20. The method of claim 15, wherein the providing step includes providing hard decisions for the code channels of interfering users.
